(19) United States
(12) Patent Application Publication
(10) Pub. No.: US 2026/0362683 A1
(43) Pub. Date: Nov. 12, 2026

(54) SEMICONDUCTOR DEVICE AND MANUFACTURING METHOD OF THE SAME

(71) Applicant: SK hynix Inc., Gyeonggi-do (KR)

(72) Inventor: Heon Yong CHANG, Gyeonggi-do (KR)

(21) Appl. No.: 19/315,868

(22) Filed: Sep. 2, 2025

(30) Foreign Application Priority Data
May 9, 2025 (KR) 10-2025-0060127

(51) Int. Cl. H10B 12/00; H10W 20/20; H10W 20/41

(52) U.S. Cl. CPC H10B 12/50; H10B 12/09; H10B 12/315; H10B 12/34; H10W 20/213; H10W 20/435

(57) ABSTRACT

A semiconductor device is provided. The semiconductor device may include: a substrate including a cell region and a peripheral region; a first contact disposed in the peripheral region; a first interlayer insulating film disposed on the first contact; a first wiring connected to the first contact through the first interlayer insulating film; and a second interlayer insulating film disposed on the first wiring and spaced apart from the first interlayer insulating film.

### CROSS-REFERENCE TO RELATED APPLICATIONS

The present application claims priority under 35 U.S.C. §119(a) to Korean Patent Application No. 10-2025-0060127 filed on May 9, 2025, which is incorporated herein by reference in its entirety.

### BACKGROUND

### 1. Technical Field

Embodiments of the present disclosure relate to a semiconductor device and a method of manufacturing the same.

### 2. Related Art

As the integration density of semiconductor devices increases, the spacing between internal wirings becomes narrower. As a result, the likelihood of interference effects such as short circuits or parasitic capacitance between nearby wirings increases. Such interference may compromise process reliability or device stability. Accordingly, technical solutions to suppress such interference are becoming increasingly important.

### SUMMARY

Embodiments of the present disclosure may provide a semiconductor device and a method of manufacturing the same, which can minimize interference between nearby wirings.

Embodiments of the present disclosure may provide a semiconductor device. The semiconductor device may include: a substrate including a cell region and a peripheral region; a first contact disposed in the peripheral region; a first interlayer insulating film disposed on the first contact; a first wiring connected to the first contact through the first interlayer insulating film; and a second interlayer insulating film disposed on the first wiring and spaced apart from the first interlayer insulating film.

Embodiments of the present disclosure may provide a semiconductor device comprising: a substrate including a cell region and a peripheral region; a first contact disposed in the peripheral region; a first interlayer insulating film disposed on the first contact; a first insulating layer disposed on the first interlayer insulating film; a first wiring, penetrating the first insulating layer and the first interlayer insulating film, connected to the first contact; and a through electrode penetrating the first insulating layer and the first interlayer insulating film, wherein a top surface of the through electrode is coplanar with a top surface of the first wiring.

Embodiments of the present disclosure may provide a method of manufacturing a semiconductor device, the method comprising: forming a first contact in a peripheral region of a substrate, wherein the substrate includes a cell region and the peripheral region; forming a first interlayer insulating film on the first contact; penetrating the first interlayer insulating film to form a first wiring on the first contact; forming a through electrode such that a top surface of the through electrode is coplanar with a top surface of the first wiring; and forming a second interlayer insulating film in contact with the top surface of the through electrode and the top surface of the first wiring.

According to embodiments of the present disclosure, interference between nearby wirings can be minimized.

### BRIEF DESCRIPTION OF THE DRAWINGS

The drawings are provided for illustrative purposes only and are not intended to limit the scope of the present disclosure.

FIG. 1 illustrates an example of a cross-sectional structure of a semiconductor device according to an embodiment of the present disclosure.

FIG. 2 is an enlarged view of region 150 in FIG. 1.

FIGS. 3-13 are cross-sectional views for explaining a method of manufacturing a semiconductor device according to embodiments of the present disclosure.

FIG. 14 is a cross-sectional view of a semiconductor device according to another embodiment different from those of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element "is connected or coupled to", “contacts or overlaps” etc., a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc., each other via a fourth element. Here, the second element may be included in at least one of two or more elements that "are connected or coupled to", “contact or overlap”, etc., each other.

When time relative terms, such as "after," "subsequent to," "next," "before," and the like, are used to describe processes or operations of elements or configurations, or flows or steps in operating, processing, manufacturing methods, these terms may be used to describe non-consecutive or non-sequential processes or operations unless the term "directly" or "immediately" is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

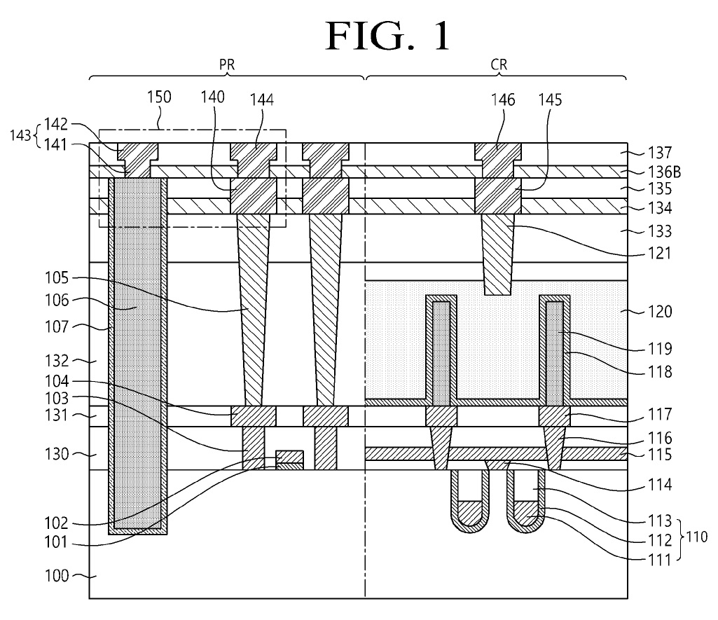

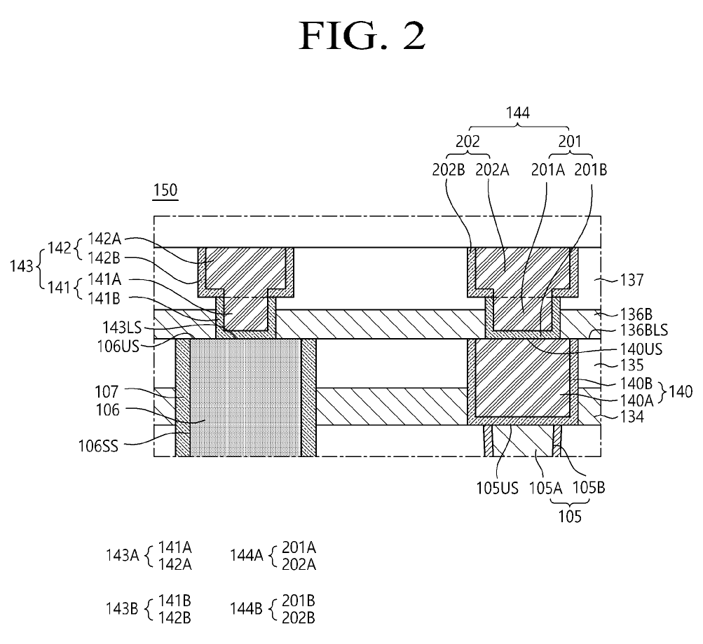

FIG. 1 is a cross-sectional view for illustrating a semiconductor device according to an embodiment of the present disclosure. FIG. 2 is an enlarged view of region 150 in FIG. 1.

Referring to FIGS. 1 and 2, the semiconductor device may include: a substrate 100; a gate insulating layer 101; a gate 102; a lower contact plug 103; a lower wiring 104; a first contact 105; a through electrode 106; a through electrode barrier layer 107; a gate structure 110; a bit line contact 114; a bit line 115; a contact plug 116; a landing pad 117; a dielectric layer 118; a first electrode 119; a second electrode 120; a second contact 121; a separation insulating layer 130; a first capping layer 131; a second capping layer 132; a third capping layer 133; a first interlayer insulating film 134; a first insulating layer 135; a second interlayer insulating film 136B; a second insulating layer 137; a first wiring 140; a second wiring 143; a third wiring 144; a fourth wiring 145; and a fifth wiring 146.

The substrate 100 may include a semiconductor substrate such as a silicon wafer or a silicon-on-insulator (SOI) wafer. The substrate 100 may also include a group III-V compound semiconductor substrate, for example, GaAs. The substrate 100 may include single-crystal silicon, polysilicon, amorphous silicon, single-crystal silicon germanium, polycrystalline silicon germanium, carbon-doped silicon, or a combination thereof.

Although not shown, the substrate 100 may include at least one device isolation layer in a cell region (CR) and a peripheral region (PR). The device isolation layer may be formed by a trench isolation technique such as shallow trench isolation (STI). The device isolation layer may include silicon oxide, silicon nitride, silicon oxynitride, low-k dielectric, high-k dielectric, or a combination thereof.

In the cell region CR, the gate structure 110 may include a word line 111, a gate insulating film 112, and a gate capping layer 113. A top surface of the word line 111 may be positioned below a top surface of the substrate 100. The word line 111 may be a buried gate or a buried word line. The gate capping layer 113 may be disposed on the word line 111. The gate insulating film 112 may surround side surfaces of the word line 111 and the gate capping layer 113.

The word line 111 may include a conductive material such as a metal, metal oxide, metal nitride, metal silicide, polysilicon, conductive carbon, or a combination thereof. The gate capping layer 113 may include silicon oxide, silicon nitride, silicon oxynitride, low-k dielectric, high-k dielectric, or a combination thereof. The gate capping layer 113 may include silicon oxide, silicon nitride, silicon oxynitride, high-k dielectric, or a combination thereof.

In the peripheral region PR, the second wiring 143 may include a first upper via 141 and a first upper wiring 142. The first upper via 141 and the first upper wiring 142 may be simultaneously formed over the through electrode 106. In this instance, the first upper via 141 and the first upper wiring 142 may be formed through a dual damascene process. The first upper via 141 and the first upper wiring 142 may be formed by a photolithography and etching process. A width of the first upper wiring 142 may be greater than a width of the first upper via 141.

The separation insulating layer 130, the gate insulating layer 101, the gate 102, the lower contact plug 103, the bit line contact 114, and the contact plug 116 may be disposed on the substrate 100.

In the cell region CR, the bit line 115 may be disposed on the bit line contact 114. The bit line 115 may be arranged in a direction perpendicular to the word line 111. The bit line 115 may not be in contact with the contact plug 116. That is, although not illustrated, a dielectric layer may be disposed between the bit line 115 and the contact plug 116. Landing pads 117 and the first capping layer 131 may be disposed on the contact plug 116 and the separation insulating layer 130, respectively. The landing pads 117 may overlap the contact plugs 116 in a vertical direction.

In the peripheral region PR, the lower contact plugs 103, the gate 102, and the gate insulating layer 101 may be disposed on the substrate 100. The first capping layer 131 and the lower wirings 104 may be disposed on the lower contact plugs 103. The lower wirings 104 may overlap the lower contact plugs 103 in a vertical direction. In one embodiment, the lower contact plugs 103 may be source and drain (source/drain) electrodes of transistors forming various circuits located in the peripheral region, and the lower wiring 104 may be a gate electrode.

In the peripheral region PR, the through electrode 106 may penetrate the separation insulating layer 130, the first capping layer 131, the second capping layer 132, the third capping layer 133, the first interlayer insulating film 134, and the first insulating layer 135. The through electrode 106 may extend into the substrate 100.

The through electrode 106 may include copper (Cu), manganese (Mn), aluminum (Al), gold (Au), indium (In), nickel (Ni), or a combination thereof.

A distance from a top surface 106US of the through electrode 106 to a top surface of the substrate 100 may be greater than a distance from a top surface 105US of the first contact 105 to the top surface of the substrate 100. The top surface 106US of the through electrode 106 may be in contact with a bottom surface 136BLS of the second interlayer insulating film 136B. The top surface 106US of the through electrode 106 may be coplanar with a top surface 140US of the first wiring 140.

The first contact 105 in the peripheral region PR may penetrate the second capping layer 132 and the third capping layer 133. The first contact 105 may be electrically connected to the lower wiring 104. The first contact 105 may be formed of a conductive material. The first contact 105 may have a column shape in a cross-sectional view. For example, it may have inclined sidewalls whose width decreases toward the substrate 100 in cross-section. A plurality of first contacts 105 may be provided on the substrate 100.

The second contact 121 in the cell region CR may penetrate the second capping layer 132 and the third capping layer 133. The second contact 121 may be electrically connected to the fourth wiring 145 and the second electrode 120. The second contact 121 may be formed of a conductive material. A top surface of the second contact 121 may be in contact with a bottom surface of the first interlayer insulating film 134 and a bottom surface of the fourth wiring 145. For example, the second contact 121 may have inclined sidewalls whose width decreases toward the substrate 100 in cross-section.

For example, although not illustrated, the second contact 121 may include a barrier layer. The second contact 121 may include a conductive material such as copper. The top surface of the second contact 121 may be coplanar with the top surface 105US of the first contact 105.

The first wiring 140 disposed in the peripheral region PR may penetrate the first interlayer insulating film 134 and the first insulating layer 135. The first wiring 140 may cover the top surface of the first contact 105. The first wiring 140 may be electrically connected to the third wiring 144. A bottom surface of the first wiring 140 may be coplanar with a bottom surface of the first interlayer insulating film 134. A top surface of the first wiring 140 may be in contact with the second interlayer insulating film 136B. A plurality of first wirings 140 may be provided on the substrate 100.

The second wiring 143 disposed in the peripheral region PR may include a first upper wiring 142 and a first upper via 141. The first upper wiring 142 may be electrically connected to the first upper via 141. The second wiring 143 may penetrate the second interlayer insulating film 136B and the second insulating layer 137.

A bottom surface 143LS of the second wiring 143 may be electrically connected to the top surface 106US of the through electrode 106. A top surface of the second wiring 143 may be coplanar with a top surface of the third wiring 144. A width of the bottom surface 143LS of the second wiring 143 may be less than a width of the top surface 106US of the through electrode 106.

In the peripheral region PR, the third wiring 144 may be disposed on the first wiring 140. The third wiring 144 may include a second upper wiring 202 and a second upper via 201. The third wiring 144 may penetrate the second insulating layer 137 and the second interlayer insulating film 136B. A top surface of the third wiring 144 may be coplanar with a top surface of the second insulating layer 137. The third wiring 144 may be electrically connected to the top surface 140US of the first wiring 140.

In the cell region CR, the fourth wiring 145 may penetrate the first interlayer insulating film 134 and the first insulating layer 135. The fourth wiring 145 may be electrically connected to the second contact 121 and the fifth wiring 146. A top surface of the fourth wiring 145 may be in contact with a bottom surface of the second interlayer insulating film 136B. The top surface of the fourth wiring 145 may be coplanar with the top surface of the first wiring 140 and the top surface 106US of the through electrode 106.

In the cell region CR, the fifth wiring 146 may be disposed on the fourth wiring 145. In one embodiment, the fifth wiring 146 may include a third upper wiring and a third upper via. The fifth wiring 146 may penetrate the second insulating layer 137 and the second interlayer insulating film 136B. The fifth wiring 146 may be electrically connected to the fourth wiring 145. The fifth wiring 146 may include the same material as the second wiring 143 and the third wiring 144.

The first interlayer insulating film 134 may be disposed on the third capping layer 133. The first insulating layer 135 may be disposed on the first interlayer insulating film 134. The second interlayer insulating film 136B may be spaced apart from the first interlayer insulating film 134. The second interlayer insulating film 136B may be disposed between the first insulating layer 135 and the second insulating layer 137. The second insulating layer 137 may be disposed on the second interlayer insulating film 136B.

The first insulating layer 135 and the second insulating layer 137 may include oxides such as Boro-phospho-silicate glass (BPSG), Phospho-silicate glass (PSG), Spin-on-glass (SOG), Tetraethyl orthosilicate (TEOS), or High Density Plasma (HDP). The first capping layer 131, the second capping layer 132, and the third capping layer 133 may include the same material as the first insulating layer 135 and the second insulating layer 137.

The first interlayer insulating film 134 and the second interlayer insulating film 136B may include a material different from that of the first insulating layer 135 and the second insulating layer 137. For example, the first interlayer insulating film 134 and the second interlayer insulating film 136B may include a nitride.

The bit line contact 114, bit line 115, contact plug 116, landing pad 117, lower contact plug 103, gate 102, and lower wiring 104 may include a conductive material such as metal, metal oxide, metal nitride, metal silicide, polysilicon, conductive carbon, or a combination thereof.

In the cell region CR, the first electrode 119, the dielectric layer 118, and the second electrode 120 may be disposed on the first capping layer 131 and the landing pad 117. The first electrode 119, dielectric layer 118, and second electrode 120 may form a capacitor of a memory cell. In one embodiment, an etch stop layer may be further disposed between the first capping layer 131 and the dielectric layer 118.

The first electrode 119 may vertically overlap the landing pad 117. In one embodiment, a support pattern layer may be disposed on sidewalls of the first electrode 119. The support pattern layer may surround the sidewalls of the first electrode 119. The support pattern layer disposed on a side surface of one first electrode 119 may be separated from a support pattern layer disposed on a side surface of another first electrode 119.

The dielectric layer 118 may be disposed to cover surfaces of the first electrode 119 and the support pattern layer. The second electrode 120 may be disposed on the dielectric layer 118. A top surface of the second electrode 120 may be higher than a top surface of the first electrode 119.

The first electrode 119 and the second electrode 120 may include a conductive material such as metal, metal oxide, metal nitride, metal silicide, polysilicon, conductive carbon, or a combination thereof. The dielectric layer 118 may include a high-k dielectric material, silicon oxide, silicon nitride, or a combination thereof.

Referring to FIG. 2, the first wiring 140 may include a first wiring conductive layer 140A and a first wiring barrier portion 140B. The first wiring barrier portion 140B may surround a bottom surface and sidewalls of the first wiring conductive layer 140A. The first wiring barrier portion 140B may include a conductive material such as copper (Cu), tungsten (W), tantalum nitride (TaN), or a combination thereof. In one embodiment, the first wiring conductive layer 140A may include a conductive material such as copper (Cu) or manganese (Mn).

A bottom surface of the first wiring 140 may be in contact with a top surface 105US of the first contact 105 and a bottom surface of the first interlayer insulating film 134. A top surface 140US of the first wiring 140 may be in contact with a bottom surface 136BLS of the second interlayer insulating film 136B and a bottom surface of the third wiring 144. A width of the first wiring 140 may be greater than a width of a first upper via 141 of the third wiring 144.

The top surface 105US of the first contact 105 may be in contact with bottom surfaces of the first interlayer insulating film 134 and of the third wiring 144. The first contact 105 may include a first contact conductive layer 105A and a first contact barrier portion 105B. The first contact conductive layer 105A may include a conductive material such as copper (Cu) or tungsten (W). The first contact barrier portion 105B may include a conductive material such as copper (Cu), tungsten (W), tantalum nitride (TaN), or a combination thereof.

The through electrode barrier layer 107 may be disposed on a side surface 106SS of the through electrode 106. The through electrode barrier layer 107 may include a metal, a metal nitride, or a combination thereof, such as tantalum (Ta), tantalum nitride (TaN), titanium (Ti), titanium nitride (TiN), ruthenium (Ru), cobalt (Co), nickel (Ni), nickel-boron alloy (NiB), or tungsten nitride (WN). The through electrode barrier layer 107 may surround a bottom surface and side surface 106SS of the through electrode 106.

A top surface of the through electrode 106 may be in contact with a bottom surface of the second interlayer insulating film 136B and a first upper via 141 of the second wiring 143. The second wiring 143 may be disposed on the through electrode 106. A width of the through electrode 106 may be greater than a width of the second wiring 143. The first insulating layer 135 may surround a side surface of the through electrode 106.

The first upper via 141 may include a first upper via barrier portion 141B and a first upper via conductive layer 141A. The first upper wiring 142 may include a first upper wiring barrier portion 142B and a first upper wiring conductive layer 142A.

The second wiring 143 may include a second wiring barrier portion 143B and a second wiring conductive layer 143A. The second wiring barrier portion 143B may include the first upper via barrier portion 141B and the first upper wiring barrier portion 142B. The second wiring conductive layer 143A may include the first upper via conductive layer 141A and the first upper wiring conductive layer 142A.

The second wiring barrier portion 143B may include a conductive material such as titanium (Ti), tantalum (Ta), tantalum nitride (TaN), titanium nitride (TiN), or a combination thereof. In one embodiment, the second wiring conductive layer 143A may include a conductive material such as copper (Cu) or manganese (Mn).

The first upper via barrier portion 141B may surround a bottom surface and sidewalls of the first upper via conductive layer 141A. The first upper wiring barrier portion 142B may surround sidewalls and a part of a bottom surface of the first upper wiring conductive layer 142A. A bottom surface 143LS of the second wiring 143 may be in contact with a top surface of the through electrode 106.

The third wiring 144 may include a second upper via 201 and a second upper wiring 202. The second upper via 201 may include a second upper via conductive layer 201A and a second upper via barrier portion 201B. The second upper wiring 202 may include a second upper wiring conductive layer 202A and a second upper wiring barrier portion 202B.

The third wiring 144 may include a third wiring conductive layer 144A and a third wiring barrier portion 144B. The third wiring conductive layer 144A may include the second upper via conductive layer 201A and the second upper wiring conductive layer 202A. The third wiring barrier portion 144B may include the second upper via barrier portion 201B and the second upper wiring barrier portion 202B. The third wiring barrier portion 144B may include a conductive material such as titanium (Ti), tantalum (Ta), tantalum nitride (TaN), titanium nitride (TiN), or a combination thereof. In one embodiment, the third wiring conductive layer 144A may include a conductive material such as copper (Cu) or manganese (Mn).

The second upper via barrier portion 201B may surround a bottom surface and sidewalls of the second upper via conductive layer 201A. The second upper wiring barrier portion 202B may surround sidewalls and a part of a bottom surface of the second upper wiring conductive layer 202A. A bottom surface of the third wiring 144 may be in contact with a top surface 140US of the first wiring 140 and a bottom surface 136BLS of the second interlayer insulating film 136B.

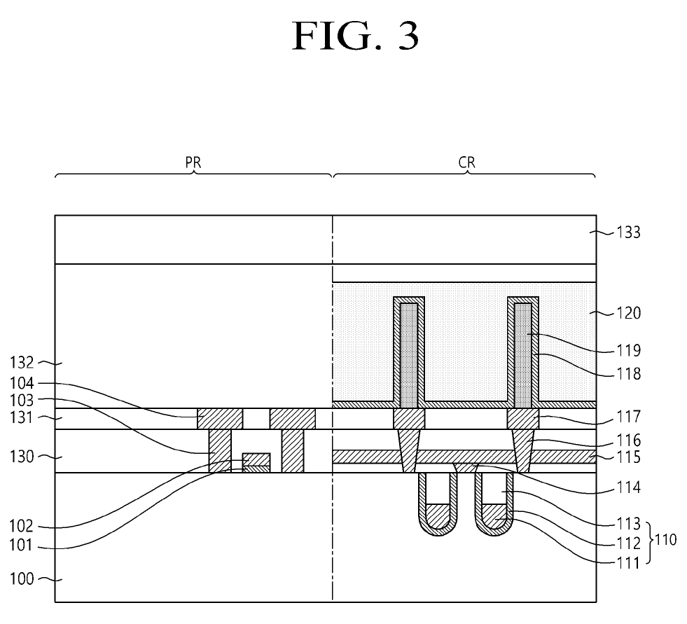

FIGS. 3-13 are cross-sectional views for illustrating a method of manufacturing a semiconductor device according to embodiments of the present disclosure.

Referring to FIG. 3, the gate structure 110 may be formed in a cell region CR. The separation insulating layer 130 may be formed on the substrate 100. The bit line contact 114, the bit line 115, and the contact plug 116 may be formed in the separation insulating layer 130. The first capping layer 131 and the landing pad 117 may be formed on the separation insulating layer 130. The second capping layer 132 may be disposed on the first capping layer 131. The first electrode 119, the dielectric layer 118, and the second electrode 120 may be formed on the second capping layer 132.

The gate insulating layer 101, and the lower contact plug 103 may be formed in the separation insulating layer 130 on the substrate 100 in the peripheral region PR, the gate 102. The lower wiring 104 may be formed in the first capping layer 131 on the separation insulating layer 130. The second capping layer 132 may be disposed on the first capping layer 131.

After depositing the second capping layer 132, a top surface of the second capping layer 132 may be partially removed through a planarization process. The planarization process may include a chemical mechanical polishing (CMP) process. The third capping layer 133 may be formed on the planarized second capping layer 132. In one embodiment, the third capping layer 133 may include an oxide.

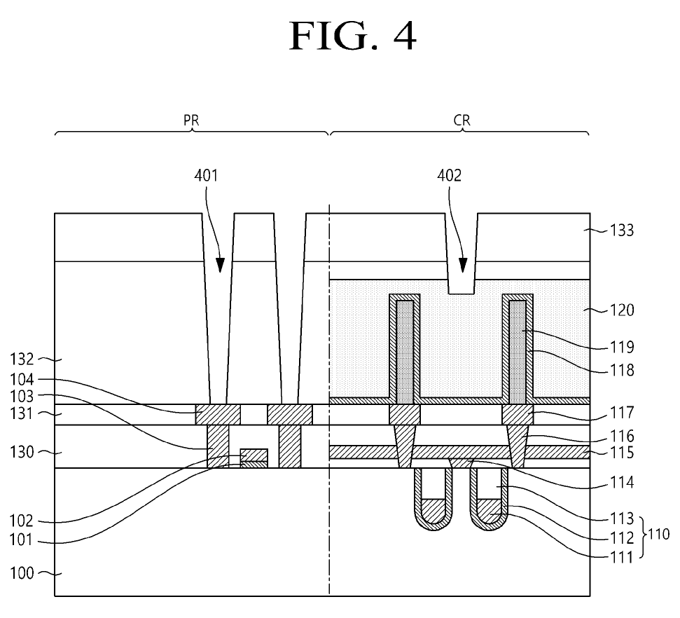

Referring to FIG. 4, contact holes may be formed through the second capping layer 132 and the third capping layer 133. The contact holes may include a first contact hole 401 formed in the peripheral region PR and a second contact hole 402 formed in the cell region CR. The first contact hole 401 may be in contact with a top surface of the lower wiring 104. The second contact hole 402 may be connected to the second electrode 120. When forming the first contact hole 401, parts of the second capping layer 132 and the third capping layer 133 may be removed.

The first contact hole 401 may have a structure that exposes at least a portion of the lower wiring 104. The second contact hole 402 may have a structure that exposes at least a portion of the second electrode 120. A height of the first contact hole 401 formed in the peripheral region PR may be greater than a height of the second contact hole 402 formed in the cell region CR.

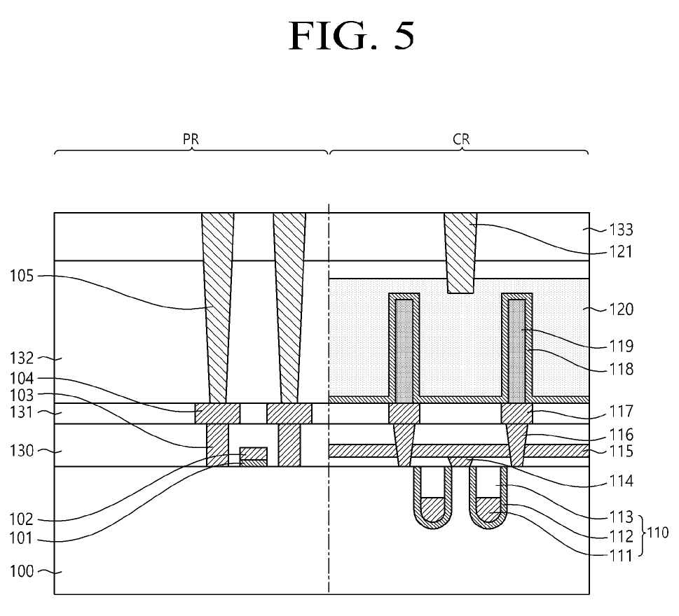

Referring to FIG. 5, in the peripheral region PR, the first contact 105 may be formed to fill the first contact hole 401. A bottom surface of the first contact 105 may be in contact with the lower wiring 104. A top surface of the first contact 105 may be coplanar with a top surface of the third capping layer 133. At least one first contact 105 may be provided on the substrate 100.

In the cell region CR, the second contact 121 may be arranged to fill the second contact hole 402. A bottom surface of the second contact 121 may be connected to the second electrode 120. The top surfaces of the first contact 105, the second contact 121, and the third capping layer 133 may be coplanar.

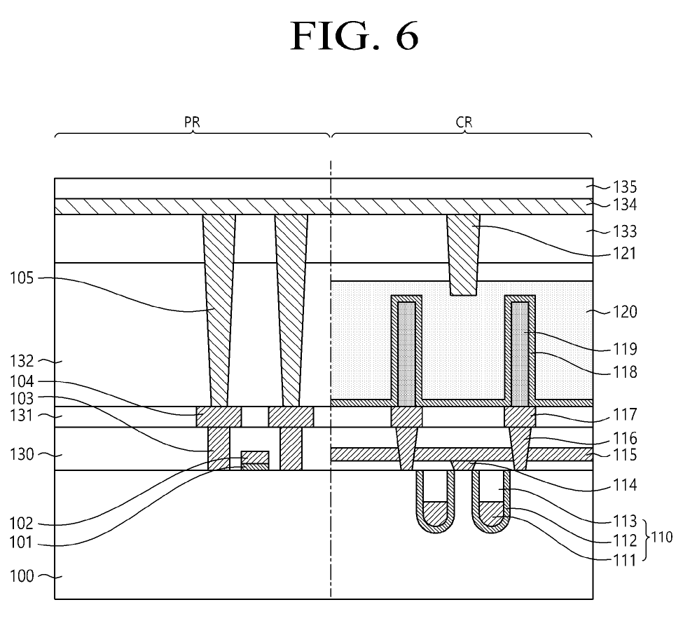

Referring to FIG. 6, the first interlayer insulating film 134 is formed on the third capping layer 133. The first interlayer insulating film 134 may be formed to cover upper portions of the first contact 105 and the second contact 121. The first interlayer insulating film 134 may prevent oxidation of the top surfaces of the first contact 105 and the second contact 121.

The first insulating layer 135 is formed on the first interlayer insulating film 134. In one embodiment, the first insulating layer 135 may include an oxide such as BPSG, PSG, SOG, TEOS, or HDP. The first interlayer insulating film 134 may include a material different from that of the first insulating layer 135.

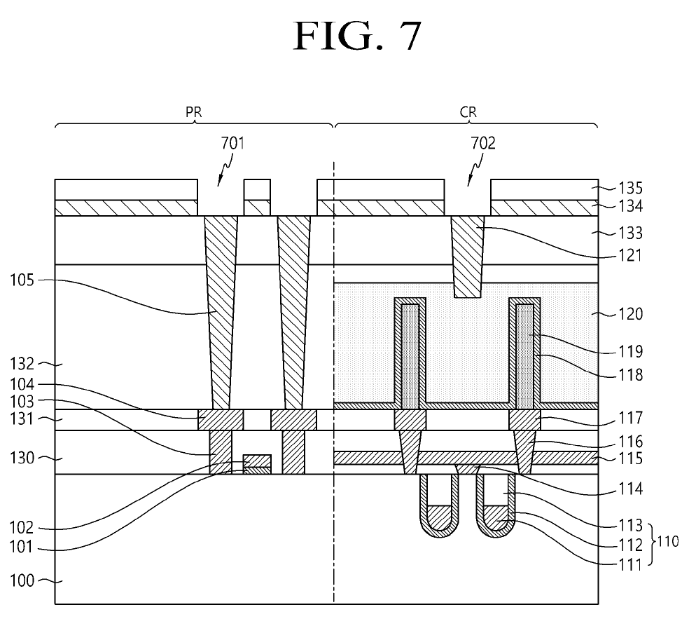

Referring to FIG. 7, the first interlayer insulating film 134 and the first insulating layer 135 are etched to form a first wiring hole 701. The first wiring hole 701 may be formed by etching a portion of the first interlayer insulating film 134 to expose the top surface of the first contact 105. During formation of the first wiring hole 701, parts of the sidewalls of the first interlayer insulating film 134 and the first insulating layer 135 may be exposed.

A fourth wiring hole 702 may be formed by etching the first interlayer insulating film 134 and the first insulating layer 135. The fourth wiring hole 702 may be formed by etching a portion of the first interlayer insulating film 134 to expose a top surface of the second contact 121. During formation of the fourth wiring hole 702, parts of the sidewalls of the first interlayer insulating film 134 and the first insulating layer 135 may be exposed.

In one embodiment, the process of exposing the top surfaces of the first contact 105 and the second contact 121 may include a photolithography and etching process.

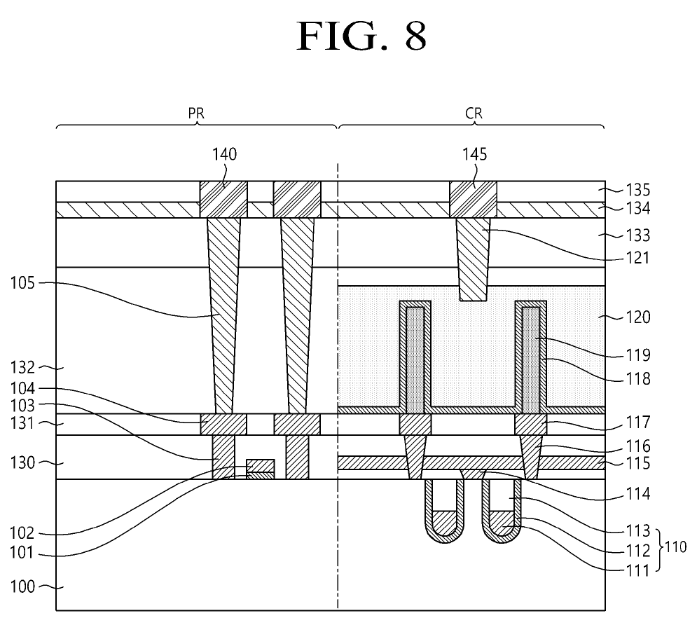

Referring to FIG. 8, a barrier portion (not shown) may be formed along the inner sidewalls and bottom surfaces of the first wiring hole 701 and the fourth wiring hole 702. Then, a conductive material may be deposited in the first wiring hole 701 and the fourth wiring hole 702 to form the first wiring 140 and a fourth wiring 145. A plurality of first wirings 140 may be provided on the substrate 100.

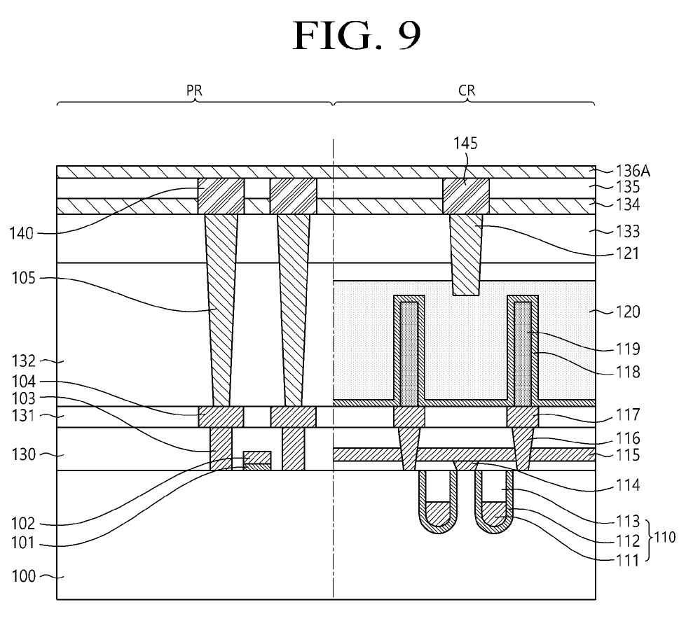

Referring to FIG. 9, a nitride layer 136A may be formed on the first insulating layer 135. The nitride layer 136A may include a material different from that of the first insulating layer 135. In one embodiment, the nitride layer 136A may include a nitride. The nitride layer 136A may be in contact with top surfaces of the first wirings 140 and the fourth wiring 145.

In one embodiment, the nitride layer 136A may function as a barrier to prevent diffusion of a metal material into other regions during a subsequent formation process of the through electrode 106. The nitride layer 136A may function to control oxidation of the first wirings 140 and the fourth wiring 145.

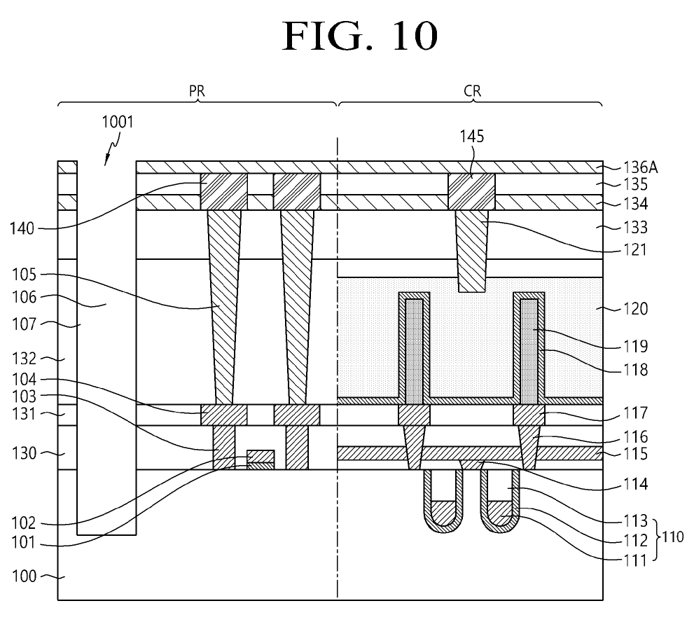

Referring to FIG. 10, a through electrode hole 1001 may penetrate the nitride layer 136A, the first insulating layer 135, the first interlayer insulating film 134, the third capping layer 133, the second capping layer 132, the first capping layer 131, and the separation insulating layer 130. The through electrode hole 1001 may extend into the substrate 100. The through electrode hole 1001 may be formed through a photolithography and etching process. The through electrode 106 may be formed inside the through electrode hole 1001 in a subsequent process.

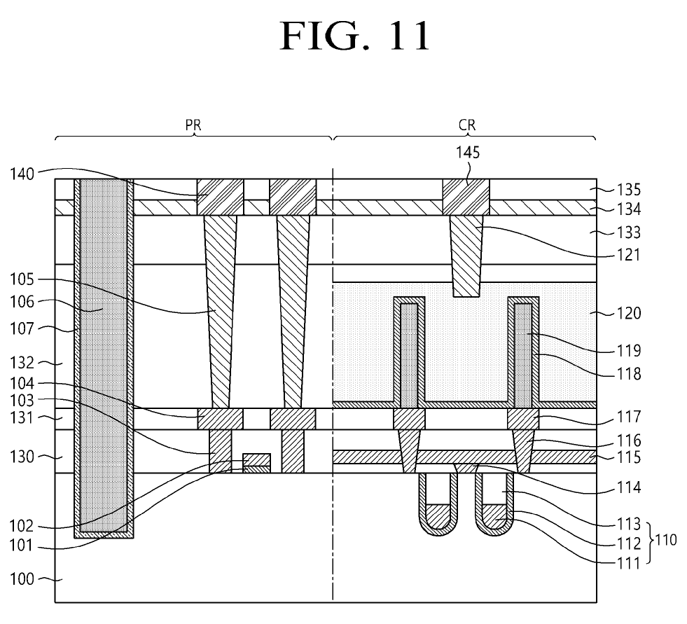

Referring to FIG. 11, the through electrode barrier layer 107 may be formed inside the through electrode hole 1001. The through electrode barrier layer 107 may include tantalum (Ta), tantalum nitride (TaN), titanium (Ti), titanium nitride (TiN), ruthenium (Ru), cobalt (Co), nickel (Ni), nickel-boron alloy (NiB), tungsten nitride (WN), or a combination thereof.

After forming the through electrode barrier layer 107, a conductive material may be deposited inside to form the through electrode 106. In this instance, the through electrode 106 may include copper (Cu), manganese (Mn), or a combination thereof.

After forming the through electrode 106, the nitride layer 136A may be etched to expose an upper portion of the first insulating layer 135. The etching process may include a chemical mechanical polishing (CMP) process. Through the etching process, top surfaces of the through electrode 106, the first wirings 140, and the fourth wiring 145 may become coplanar.

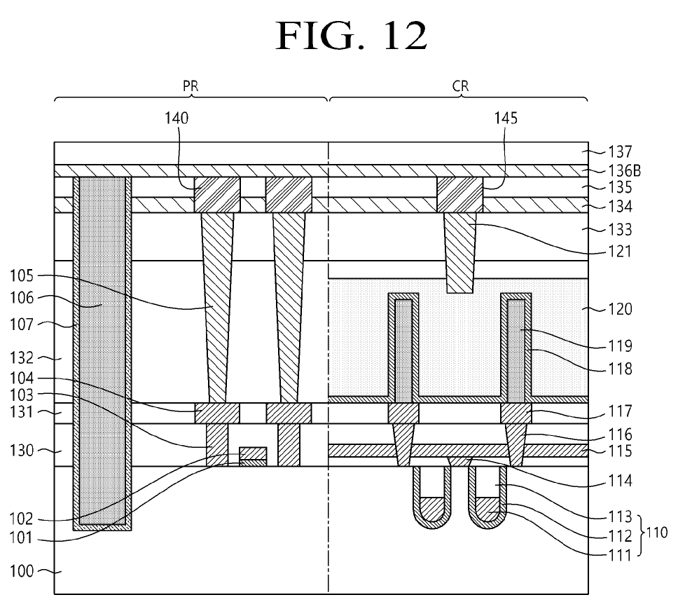

Referring to FIG. 12, the second interlayer insulating film 136B may be formed in a region where the nitride layer 136A has been removed. The second interlayer insulating film 136B may be disposed on the first insulating layer 135. The second interlayer insulating film 136B may be in contact with top surfaces of the through electrode 106, the first wirings 140, and the fourth wiring 145. The second interlayer insulating film 136B may prevent oxidation of the through electrode 106, the first wirings 140, and the fourth wiring 145.

The second insulating layer 137 may be formed on the second interlayer insulating film 136B. The second insulating layer 137 may include a material different from that of the second interlayer insulating film 136B. In one embodiment, the first insulating layer 135 may include an oxide such as BPSG, PSG, SOG, TEOS, or HDP.

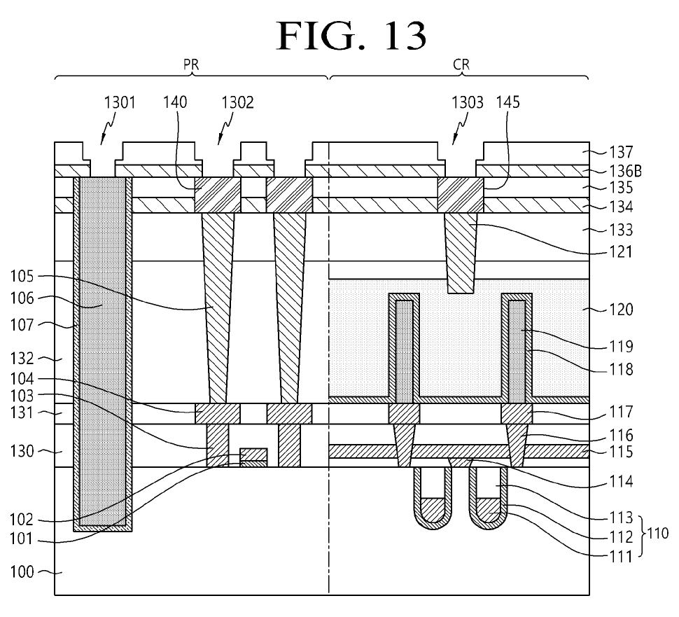

Referring to FIG. 13, a second wiring hole 1301, a third wiring hole 1302, and a fifth wiring hole 1303 may be formed through the second insulating layer 137 and the second interlayer insulating film 136B. The second wiring hole 1301 may be in contact with a top surface of the through electrode 106. The third wiring hole 1302 may be in contact with a top surface of the first wiring 140. The fifth wiring hole 1303 may be in contact with a top surface of the fourth wiring 145.

In one embodiment, the second wiring hole 1301, the third wiring hole 1302, and the fifth wiring hole 1303 may be formed by a photolithography and etching process. When forming the second wiring hole 1301, the third wiring hole 1302, and the fifth wiring hole 1303, portions of the sidewalls of the second interlayer insulating film 136B and the second insulating layer 137 may be exposed.

A width of a bottom surface of the second wiring hole 1301 may be less than a width of a top surface of the through electrode 106. A width of a bottom surface of the third wiring hole 1302 may be less than a width of a top surface of the first contact 105. A width of a bottom surface of the fourth wiring hole 702 may be less than a width of a top surface of the second contact 121.

Referring again to FIGS. 13 and 1, a barrier portion (not shown) may be formed along inner sidewalls and bottom surfaces of the second wiring hole 1301, the third wiring hole 1302, and the fifth wiring hole 1303. The barrier portions of the second wiring 143, the third wiring 144, and the fifth wiring 146 may include titanium (Ti), tantalum (Ta), tantalum nitride (TaN), titanium nitride (TiN), or a combination thereof.

After forming the barrier portions in the second wiring hole 1301, the third wiring hole 1302, and the fifth wiring hole 1303, a conductive material may be deposited to form the second wiring 143, the third wiring 144, and the fifth wiring 146. A conductive material may be deposited inside the second wiring 143, the third wiring 144, and the fifth wiring 146. The conductive material may include copper (Cu), tungsten (W), manganese (Mn), or a combination thereof.

Surfaces of the second wiring 143, the third wiring 144, and the fifth wiring 146 may be planarized. The planarization process may include a chemical mechanical polishing (CMP) process. Through the planarization process, top surfaces of the second wiring 143, the third wiring 144, and the fifth wiring 146 may become coplanar.

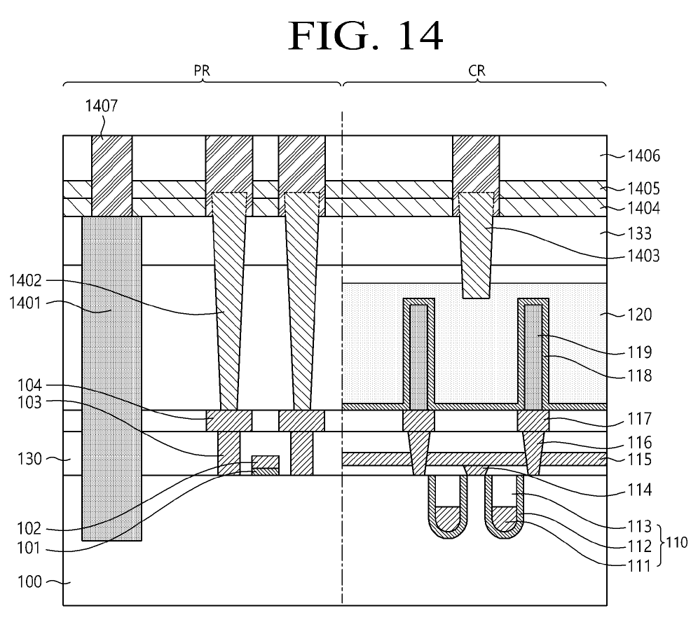

FIG. 14 illustrates an example of a cross-sectional structure of a semiconductor device different from the semiconductor device according to embodiments of the present disclosure.

Referring to FIG. 14, after a through electrode 1401 is formed, a first nitride film 1404 may be formed. A first contact 1402 may be formed on the through electrode 1401. A second nitride film 1405 may be formed on the first contact. The first nitride film 1404 and the second nitride film 1405 may be in contact with each other. Compressive stress may occur at the interface between the first nitride film 1404 and the second nitride film 1405. Accordingly, when a wiring 1407 is formed, copper migration may occur at the interface between the first nitride film 1404 and the second nitride film 1405. As a result, a short circuit may occur between wirings.

According to embodiments of the present disclosure, the first wirings 140 and the fourth wiring 145 may be formed first, and then the through electrode 106 may be formed. In this process, a nitride film for preventing oxidation of the through electrode 106 may not be formed between the first wirings 140 and the fourth wiring 145. The nitride film (first interlayer insulating film 134) formed on the first contact 105, the nitride film (second interlayer insulating film 136B) formed on the through electrode 106, the first wirings 140, and the fourth wiring 145 may be formed separately from each other. Accordingly, copper migration occurring at the interface between nitride films in contact with each other may be minimized.

Based on embodiments of the disclosed technology described above, the operation delay time of the memory system may be advantageously reduced or minimized. In addition, based on an embodiment of the disclosed technology, an overhead occurring in the process of calling a specific function may be advantageously reduced or minimized. Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A semiconductor device comprising:
a substrate including a cell region and a peripheral region;
a first contact disposed in the peripheral region;
a first interlayer insulating film disposed on the first contact;
a first wiring connected to the first contact through the first interlayer insulating film; and
a second interlayer insulating film disposed on the first wiring and spaced apart from the first interlayer insulating film.

2. The semiconductor device according to claim 1, wherein a top surface of the first wiring is in contact with a bottom surface of the second interlayer insulating film.

3. The semiconductor device according to claim 1, further comprising a through electrode penetrating the substrate and the first interlayer insulating film.

4. The semiconductor device according to claim 3, wherein a top surface of the through electrode is in contact with a bottom surface of the second interlayer insulating film.

5. The semiconductor device according to claim 3, wherein a top surface of the through electrode is coplanar with a top surface of the first wiring.

6. The semiconductor device according to claim 3, further comprising a first insulating layer disposed between the first interlayer insulating film and the second interlayer insulating film, and surrounding a side surface of the through electrode.

7. The semiconductor device according to claim 3, further comprising:
a second wiring connected to the through electrode; and
a third wiring connected to the first wiring,
wherein the second wiring and the third wiring penetrate the second interlayer insulating film.

8. The semiconductor device according to claim 7, wherein a bottom surface of the third wiring is in contact with a top surface of the first wiring, and
wherein widths of a bottom surface of the second wiring and the bottom surface of the third wiring are less than a width of the top surface of the first wiring.

9. The semiconductor device according to claim 3, wherein a top surface of the through electrode is higher than a top surface of the first contact.

10. The semiconductor device according to claim 1, wherein the first wiring covers a top surface of the first contact, and wherein a top surface of the first wiring is in contact with a bottom surface of the second interlayer insulating film.

11. The semiconductor device according to claim 1, further comprising:
a first electrode disposed in the cell region;
a second electrode disposed on the first electrode;
a dielectric layer disposed between the first and second electrodes; and
a second contact connected to the second electrode,
wherein a top surface of the second contact is coplanar with a top surface of the first contact.

12. A semiconductor device comprising:
a substrate including a cell region and a peripheral region;
a first contact disposed in the peripheral region;
a first interlayer insulating film disposed on the first contact;
a first insulating layer disposed on the first interlayer insulating film;
a first wiring, penetrating the first insulating layer and the first interlayer insulating film, connected to the first contact; and
a through electrode penetrating the first insulating layer and the first interlayer insulating film, wherein a top surface of the through electrode is coplanar with a top surface of the first wiring.

13. The semiconductor device according to claim 12, further comprising a second interlayer insulating film disposed on the first insulating layer.

14. The semiconductor device according to claim 13, wherein a top surface of the first wiring is in contact with a bottom surface of the second interlayer insulating film.

15. The semiconductor device according to claim 13, wherein a top surface of the through electrode is in contact with a bottom surface of the second interlayer insulating film.

16. The semiconductor device according to claim 13, further comprising a second wiring penetrating the second interlayer insulating film and connected to the top surface of the through electrode and the top surface of the first wiring.

17. The semiconductor device according to claim 12, wherein a top surface of the through electrode is coplanar with a top surface of the first wiring.

18. A method of manufacturing a semiconductor device comprising:
forming a first contact in a peripheral region of a substrate, wherein the substrate includes a cell region and the peripheral region;
forming a first interlayer insulating film on the first contact;
penetrating the first interlayer insulating film to form a first wiring on the first contact;
forming a through electrode such that a top surface of the through electrode is coplanar with a top surface of the first wiring; and
forming a second interlayer insulating film in contact with the top surface of the through electrode and the top surface of the first wiring.

19. The method of manufacturing a semiconductor device according to claim 18, further comprising forming a first insulating layer between the first interlayer insulating film and the second interlayer insulating film.

20. The method of manufacturing a semiconductor device according to claim 19,
wherein the first interlayer insulating film and the second interlayer insulating film comprise a nitride, and
wherein the first insulating layer comprises an oxide.
